(19) United States
(12) Patent Application Publication
(10) Pub. No.: US 2026/0246223 A1
(43) Pub. Date: Aug. 20, 2026

(54) SOLID-STATE LASER SYSTEM AND EXCIMER LASER APPARATUS

(71) Applicant: Gigaphoton Inc., Tochigi (JP)

(72) Inventor: Seiji NOGIWA, Tochigi (JP)

(73) Assignee: Gigaphoton Inc., Tochigi (JP)

(21) Appl. No.: 19/439,287

(22) Filed: Jan. 2, 2026

(30) Foreign Application Priority Data
Feb. 19, 2025 (JP) 2025-025297

(51) Int. Cl. H01S 3/094; G02F 1/355; G02F 1/37; G02F 1/39; H01S 3/08; H01S 3/0941; H01S 3/108; H01S 3/16; H01S 3/225

(52) U.S. Cl. CPC H01S 3/094076; G02F 1/3551; G02F 1/37; G02F 1/392; H01S 3/08013; H01S 3/09415; H01S 3/1083; H01S 3/1618; H01S 3/2251

(57) ABSTRACT

A solid-state laser system according to one aspect of the present disclosure includes a first semiconductor laser device configured to output a first pulse laser beam having a first wavelength, and a first burst pulse light generating apparatus including a first generation stage that generates a first burst pulse light beam including two pulse laser beams by branching the first pulse laser beam into a first branch light beam and a second branch light beam, and then coupling the first branch light beam and the second branch light beam. The first generation stage includes a first optical path having a first optical path length for propagating the first branch light beam, and a second optical path having a second optical path length, which is longer than the first optical path length, for propagating the second branch light beam.

### CROSS-REFERENCE TO RELATED APPLICATIONS

The present application claims the benefit of Japanese Patent Application No. 2025-025297, filed on Feb. 19, 2025, the entire contents of which are hereby incorporated by reference.

### BACKGROUND

### 1. Technical Field

The present disclosure relates to a solid-state laser system and an excimer laser apparatus.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

In addition, excimer laser beams are sometimes used for direct processing of a polymer material, a glass material, or the like, since a pulse width is several tens of ns and a wavelength is as short as about 248 nm and about 193 nm, respectively. A chemical bond in a polymer material can be cut by an excimer laser beam having photon energy higher than bond energy. Therefore, it is known that non-heating processing of a polymer material is made possible by an excimer laser beam, and a processing shape becomes smooth. Further, since glass, ceramics, and the like have a high absorptance to an excimer laser beam, it is known that even a material that is difficult to be processed by visible and infrared laser beams can be processed by an excimer laser beam.

### LIST OF DOCUMENTS

### Patent Documents

Patent Document 1: US Patent Application Publication No. 2021/0226411
Patent Document 2: Japanese Unexamined Patent Application Publication No. 63-028088
Patent Document 3: Japanese Unexamined Patent Application Publication No. 2005-159522

### SUMMARY

A solid-state laser system according to one aspect of the present disclosure includes a first semiconductor laser device and a first burst pulse light generating apparatus. The first semiconductor laser device is configured to output a first pulse laser beam having a first wavelength. The first burst pulse light generating apparatus includes a first generation stage that generates a first burst pulse light beam including two pulse laser beams by branching the first pulse laser beam into a first branch light beam and a second branch light beam, and then coupling the first branch light beam and the second branch light beam. The first generation stage includes a first optical path having a first optical path length for propagating the first branch light beam, and a second optical path having a second optical path length, which is longer than the first optical path length, for propagating the second branch light beam.

An excimer laser apparatus according to one aspect of the present disclosure includes a solid-state laser system, a wavelength conversion system, and an amplifier. The solid-state laser system includes a first semiconductor laser device configured to output a first pulse laser beam having a first wavelength, and a first burst pulse light generating apparatus including a first generation stage that generates a first burst pulse light beam including two pulse laser beams by branching the first pulse laser beam into a first branch light beam and a second branch light beam, and then coupling the first branch light beam and the second branch light beam. The first generation stage includes a first optical path having a first optical path length for propagating the first branch light beam, and a second optical path having a second optical path length, which is longer than the first optical path length, for propagating the second branch light beam. The wavelength conversion system is configured to generate and output a seed light beam based on the first burst pulse light beam. The amplifier is configured to amplify the seed light beam.

A solid-state laser system according to one aspect of the present disclosure includes a semiconductor laser device and a burst pulse light generating apparatus. The semiconductor laser device is configured to output a pulse laser beam. The burst pulse light generating apparatus includes one or more generation stages that generate a burst pulse light beam by branching the pulse laser beam into two and then coupling the branch light beams. The burst pulse light generating apparatus includes, when n is an integer equal to or larger than one, n pieces of the generation stages connected in series, and generates the burst pulse light beam including 2ⁿ pieces of pulse laser beams.

### BRIEF DESCRIPTION OF THE DRAWINGS

Some embodiments of the present disclosure will be described below, by way of example only, with reference to the accompanying drawings.

FIG. 1 is a diagram schematically illustrating a configuration of an excimer laser system according to a comparative example.

FIG. 2 is a diagram schematically illustrating a configuration of an excimer laser system according to a first embodiment.

FIG. 3 is a diagram illustrating a second pulse laser beam and a burst pulse light beam according to the first embodiment.

FIG. 4 is a diagram illustrating a configuration example of a burst pulse light generating apparatus.

FIG. 5 is a diagram illustrating a configuration example of an optical fiber coupler.

FIG. 6 is a diagram illustrating a configuration example of a generation stage.

FIG. 7 is a diagram illustrating a flow of generating a burst pulse light beam from a second pulse laser beam.

FIG. 8 is a diagram schematically illustrating a configuration of an excimer laser system according to a second embodiment.

FIG. 9 is a diagram illustrating a configuration example of a burst pulse light generating apparatus according to the second embodiment.

FIG. 10 is a diagram illustrating a first pulse laser beam and a burst pulse light beam according to the second embodiment.

FIG. 11 is a diagram illustrating calculated values of light intensity of pulse laser beams included in a burst pulse light beam generated by the burst pulse light generating apparatus according to the second embodiment.

FIG. 12 is a graph illustrating a difference in light intensity for each route illustrated in FIG. 11.

FIG. 13 is a diagram schematically illustrating a configuration of an excimer laser system according to a first modification.

FIG. 14 is a diagram schematically illustrating a configuration of a generation stage according to a second modification.

FIG. 15 is a diagram schematically illustrating a configuration of an excimer laser system according to a third modification.

### DESCRIPTION OF EMBODIMENTS

### Contents

1. Comparative Example
   1.1 Configuration
   1.2 Operation
   1.3 Problem
2. First Embodiment
   2.1 Configuration
   2.2 Operation
   2.3 Effect
3. Second Embodiment
   3.1 Configuration
   3.2 Operation
   3.3 Effect
4. First Modification
5. Second Modification
6. Third Modification

Hereinafter, embodiments of the present disclosure will be described in detail with reference to the drawings. The embodiments described below show some examples of the present disclosure and do not limit the contents of the present disclosure. In addition, all configurations and operations described in the embodiments are not necessarily essential as configurations and operations of the present disclosure. Here, the same components are denoted by the same reference signs, and any redundant description thereof is omitted.

### 1. Comparative Example

The comparative example of the present disclosure is an example recognized by the applicant as known only by the applicant, and is not a publicly known example admitted by the applicant.

### 1.1 Configuration

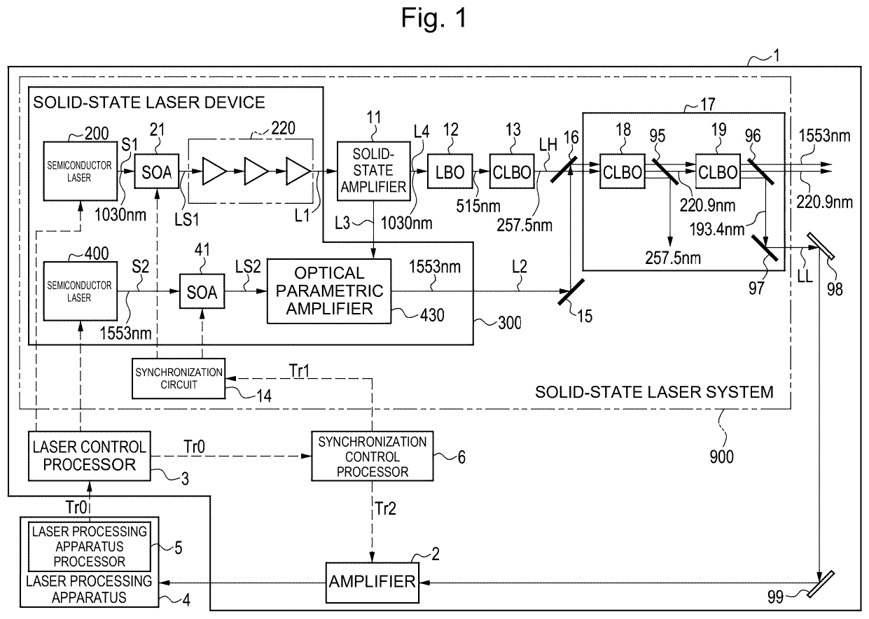

FIG. 1 schematically illustrates a configuration of an excimer laser system 1 according to the comparative example. The excimer laser system 1 includes a solid-state laser system 900, an amplifier 2, a laser control processor 3, a synchronization control processor 6, and high reflective mirrors 98 and 99.

The solid-state laser system 900 includes a solid-state laser device 300, a solid-state amplifier 11, an LBO crystal 12, a CLBO crystal 13, a synchronization circuit 14, a high reflective mirror 15, a dichroic mirror 16, and a wavelength conversion system 17.

The solid-state laser device 300 is configured to output a pulse light beam L1 that is generated based on a seed light beam S1 and has a first wavelength, and to output a burst pulse light beam L2 that is generated based on a seed light beam S2 and has a second wavelength. The first wavelength is preferably about 1030 nm, and the second wavelength is preferably about 1553 nm. In the present disclosure, a burst pulse light beam refers to a series of pulse laser beams that is formed by generating an optical pulse train intensively in a fixed period.

The solid-state laser device 300 includes a semiconductor laser 200, a semiconductor optical amplifier (SOA) 21, and a Yb fiber amplifier system 220. The semiconductor laser 200, the SOA 21, and the Yb fiber amplifier system 220 are disposed in this order from upstream to downstream along an optical path.

The semiconductor laser 200 is a distributed feedback semiconductor laser, and outputs the seed light beam S1 having a wavelength of about 1030 nm by CW oscillation. The semiconductor laser 200 may be in a single longitudinal mode and may be able to adjust a wavelength around 1030 nm.

The SOA 21 forms a pulse light generating apparatus that pulses the seed light beam S1 to generate a pulse light beam LS1. Further, as a part of a pulse light generator, an SOA or a lithium niobate modulator (LNM) that are not illustrated may be disposed in a preceding stage of the SOA 21, and the pulse light generator may be formed of the LNM.

Further, the solid-state laser device 300 includes a semiconductor laser 400, an SOA 41, and an optical parametric amplifier 430. The semiconductor laser 400, the SOA 41, and the optical parametric amplifier 430 are also disposed in this order from upstream to downstream along the optical path. The optical parametric amplifier 430 receives a part of output from the solid-state amplifier 11, which will be described later, as an excitation light beam for optical parametric amplification.

Similarly to the semiconductor laser 200, the semiconductor laser 400 is a distributed feedback semiconductor laser, and outputs the seed light beam S2 having a wavelength of about 1553 nm by CW oscillation. The semiconductor laser 400 may be in a single longitudinal mode and may be able to adjust a wavelength around 1553 nm.

The SOA 41 forms a burst pulse light generating apparatus that burst-pulses the seed light beam S2 to generate a burst pulse light beam LS2. Further, as a part of the pulse light generator, an SOA or an LNM that are not illustrated may be disposed in a preceding stage of the SOA 41, and the pulse light generator may be formed of the LNM.

The SOA 21 is a semiconductor element that converts the seed light beam S1 into a pulse laser beam having a predetermined pulse width and amplifies it further by causing a pulse current to flow to a semiconductor. The SOA 21 includes a current controller that causes the pulse current to flow to the semiconductor based on an instruction from the synchronization circuit 14.

The Yb fiber amplifier system 220 includes multiple stages of Yb-doped optical fiber amplifiers and a CW excitation semiconductor laser that outputs an excitation light beam by CW oscillation and supplies it to each optical fiber amplifier, and amplifies the pulse light beam LS1 to generate the pulse light beam L1 described above. A length of an optical fiber in the Yb fiber amplifier system 220 is limited to a length that can suppress stimulated Brillouin scattering that is a nonlinear phenomenon occurring within the optical fiber.

Similarly to the SOA 21, the SOA 41 is a semiconductor element that converts the seed light beam S2 into a plurality of pulse laser beams having a predetermined pulse width and amplifies them further by causing a pulse current to flow to a semiconductor. The SOA 41 includes a current controller that causes the pulse current to flow to the semiconductor based on an instruction from the synchronization circuit 14.

The optical parametric amplifier 430 includes a nonlinear optical crystal such as a KTP (KTiOPO₄) crystal and a periodically domain inverted lithium niobate crystal, and generates the burst pulse light beam L2 by parametrically amplifying the burst pulse light beam LS2 using an output light beam L3 from the solid-state amplifier 11 as the excitation light beam.

The synchronization circuit 14 is configured to output a predetermined trigger signal to the SOA 21 and the SOA 41, respectively, based on a trigger signal Tr1 from the synchronization control processor 6.

The solid-state amplifier 11 includes a Yb-doped crystal or ceramics. The LBO crystal 12 is a nonlinear optical crystal that outputs a pulse light beam, which is a second harmonic of a pulse light beam L4, which is a part of a pulse light beam output from the solid-state amplifier 11. The CLBO crystal 13 is a nonlinear optical crystal that outputs a pulse light beam LH having a third wavelength, which is a fourth harmonic of the pulse light beam L4. The third wavelength is about 257.5 nm. The solid-state amplifier 11, the LBO crystal 12, and the CLBO crystal 13 are disposed in this order on an optical path downstream of the Yb fiber amplifier system 220.

The high reflective mirror 15 is disposed so as to highly reflect the burst pulse light beam L2 output from the solid-state laser device 300 to be incident on the dichroic mirror 16. The dichroic mirror 16 is an optical element for which a substrate that highly transmits the pulse light beam LH is coated with a film that highly transmits the pulse light beam LH and highly reflects the burst pulse light beam L2. The dichroic mirror 16 is disposed so as to cause the pulse light beam LH and the burst pulse light beam L2 to enter the wavelength conversion system 17 while keeping their optical path axes approximately aligned.

The wavelength conversion system 17 is configured to receive the pulse light beam LH and the burst pulse light beam L2 and to output a burst pulse light beam LL having a wavelength different from both the second and third wavelengths only at a timing when the pulse light beam LH and the burst pulse light beam L2 overlap. The wavelength conversion system 17 includes CLBO crystals 18 and 19, dichroic mirrors 95 and 96, and a high reflective mirror 97. The CLBO crystal 18, the dichroic mirror 95, the CLBO crystal 19, and the dichroic mirror 96 are disposed in this order from upstream to downstream on the optical path.

The CLBO crystal 18 receives the pulse light beam LH having a wavelength of about 257.5 nm and the burst pulse light beam L2 having a wavelength of about 1553 nm. The CLBO crystal 18 outputs a burst pulse light beam having a wavelength of about 220.9 nm corresponding to a sum frequency of the wavelengths of about 257.5 nm and about 1553 nm only at a timing when the pulse light beam LH and the burst pulse light beam L2 overlap.

The dichroic mirror 95 is an optical element coated with a film that highly transmits a light beam having a wavelength of about 1553 nm and a light beam having a wavelength of about 220.9 nm and highly reflects a light beam having a wavelength of about 257.5 nm.

The CLBO crystal 19 receives two burst pulse light beams, having the wavelengths of about 1553 nm and about 220.9 nm, transmitted through the dichroic mirror 95. The CLBO crystal 19 outputs the burst pulse light beam LL having a wavelength of about 193.4 nm corresponding to a sum frequency at a timing when pulses having the wavelengths of about 1553 nm and about 220.9 nm overlap.

The dichroic mirror 96 is an optical element coated with a film that highly transmits the light beam having a wavelength of about 1553 nm and the light beam having a wavelength of about 220.9 nm and highly reflects the light beam having a wavelength of about 193.4 nm.

The high reflective mirror 97 is disposed so as to highly reflect the burst pulse light beam LL reflected by the dichroic mirror 96 to be output from the solid-state laser system 900.

The high reflective mirrors 98 and 99 are disposed such that the burst pulse light beam LL output from the solid-state laser system 900 enters amplifier 2 as a seed light beam.

The amplifier 2 is configured to amplify the seed light beam that has entered and to output it toward a laser processing apparatus 4. The amplifier 2 is an excimer laser amplifier, for example, an ArF laser amplifier using an ArF laser gas as a laser medium.

The laser control processor 3 is connected to a CW excitation semiconductor laser in the Yb fiber amplifier system 220 via a non-illustrated signal line.

To the synchronization control processor 6, an oscillation trigger signal Tr0 which instructs a generation timing of the burst pulse light beam LL to the solid-state laser system 900 is supplied from the laser processing apparatus 4 as an external device via the laser control processor 3.

The laser processing apparatus 4 includes a laser processing apparatus processor 5. The oscillation trigger signal Tr0 is supplied by the laser processing apparatus processor 5. The synchronization control processor 6 is configured to generate the trigger signal Tr1 based on the oscillation trigger signal Tr0 and to supply the generated trigger signal Tr1 to the synchronization circuit 14. In addition, the synchronization control processor 6 is configured to generate a trigger signal Tr2 based on the oscillation trigger signal Tr0 and to supply the generated trigger signal Tr2 to the amplifier 2.

### 1.2 Operation

Next, the operation of the excimer laser system 1 according to the comparative example will be described. First, the laser control processor 3 causes the semiconductor lasers 200 and 400 to perform the CW oscillation based on the oscillation trigger signal Tr0. In addition, the laser control processor 3 causes the CW excitation semiconductor laser in the Yb fiber amplifier system 220 to perform the CW oscillation based on the oscillation trigger signal Tr0.

When the oscillation trigger signal Tr0 is received from the laser processing apparatus processor 5 via the laser control processor 3, the synchronization control processor 6 controls a delay time between the oscillation trigger signal Tr0 and the trigger signal Tr1 and a delay time between the oscillation trigger signal Tr0 and the trigger signal Tr2. These delay times are set such that the amplifier 2 is operated in synchronization with a timing when the burst pulse light beam LL output from the solid-state laser system 900 enters the amplifier 2 as the seed light beam.

In the solid-state laser device 300, a CW oscillation light beam having a wavelength of about 1030 nm is output from the semiconductor laser 200 as the seed light beam S1. This seed light beam S1 is converted into the pulse light beam LS1 by the SOA 21. The pulse light beam LS1 output from the SOA 21 enters the Yb fiber amplifier system 220, is amplified by the Yb fiber amplifier system 220, and is output from the solid-state laser device 300 as the pulse light beam L1.

The pulse light beam L1 output from the solid-state laser device 300 enters the solid-state amplifier 11 and is amplified. The pulse light beam L4, which is a part of the pulse light beam amplified by the solid-state amplifier 11, is converted into the pulse light beam LH having a wavelength of about 257.5 nm by the LBO crystal 12 and the CLBO crystal 13, and is output from the CLBO crystal 13. In addition, a pulse light beam L3, which is a part of the pulse light beam amplified by the solid-state amplifier 11, enters the optical parametric amplifier 430 as the excitation light beam for the optical parametric amplification.

Further, in the solid-state laser device 300, a CW oscillation light beam having a wavelength of about 1553 nm is output from the semiconductor laser 400 as the seed light beam S2. This seed light beam S2 is converted into a burst pulse light beam LS2 by the SOA 41. The burst pulse light beam LS2 output from the SOA 41 enters the optical parametric amplifier 430, is amplified by the optical parametric amplifier 430, and is output from the solid-state laser device 300 as the burst pulse light beam L2.

The pulse light beam LH output from the CLBO crystal 13 enters the wavelength conversion system 17 via the dichroic mirror 16. In addition, the burst pulse light beam L2 output from the solid-state laser device 300 enters the wavelength conversion system 17 via the high reflective mirror 15 and the dichroic mirror 16.

Here, the synchronization circuit 14 supplies a trigger signal having a predetermined pulse width to the SOA 21 and the SOA 41 at predetermined timings based on the trigger signal Tr1. These timings are adjusted such that the pulse light beam LH enters at a timing of overlapping with the burst pulse light beam L2 in the CLBO crystal 18 of the wavelength conversion system 17.

In the wavelength conversion system 17, the pulse light beam LH and the burst pulse light beam L2 simultaneously enter the CLBO crystal 18 via the dichroic mirror 16, causing the two beams to overlap on the CLBO crystal 18. In the CLBO crystal 18, a burst pulse light beam having a wavelength of about 220.9 nm, which corresponds to the sum frequency of both, is generated only at the time when the pulse light beam LH and the burst pulse light beam L2 overlap. From the CLBO crystal 18, a pulse light beam having a wavelength of about 257.5 nm and two burst pulse light beams having wavelengths of about 1553 nm and about 220.9 nm are output.

Of the three light beams output from the CLBO crystal 18, the two burst pulse light beams having the wavelengths of about 1553 nm and about 220.9 nm are highly transmitted through the dichroic mirror 95, while the pulse light beam having a wavelength of about 257.5 nm is highly reflected by the dichroic mirror 95. The two burst pulse light beams transmitted through the dichroic mirror 95 enter the CLBO crystal 19. In the CLBO crystal 19, the burst pulse light beam LL having a wavelength of about 193.4 nm, which corresponds to the sum frequency of both, is generated. From the CLBO crystal 19, the three burst pulse light beams having the wavelengths of about 1553 nm, about 220.9 nm, and about 193.4 nm are output.

Of the three burst pulse light beams output from the CLBO crystal 19, the two burst pulse light beams having the wavelengths of about 1553 nm and about 220.9 nm are highly transmitted through the dichroic mirror 96, while the burst pulse light beam LL having a wavelength of about 193.4 nm is highly reflected by the dichroic mirror 96. The burst pulse light beam LL is highly reflected by the high reflective mirror 97 and is output from the wavelength conversion system 17.

The burst pulse light beam LL output from the wavelength conversion system 17 enters the amplifier 2 as the seed light beam via the high reflective mirrors 98 and 99. The seed light beam that has entered the amplifier 2 is amplified and is output from the amplifier 2 to the laser processing apparatus 4.

### 1.3 Problem

In the solid-state laser system 900 according to the comparative example, a burst pulse light generating apparatus for generating burst pulse light beam is formed of the SOA and the LNM, however, the SOA and the LNM are expensive and have a high risk of failure.

An object of the present disclosure is to provide a solid-state laser system that is inexpensive and has a low risk of failure, and an excimer laser system provided with the solid-state laser system.

### 2. First Embodiment

The first embodiment of the present disclosure will be described. Any component same as that described above is denoted by the same reference sign, and any redundant description thereof is omitted unless otherwise specified.

### 2.1 Configuration

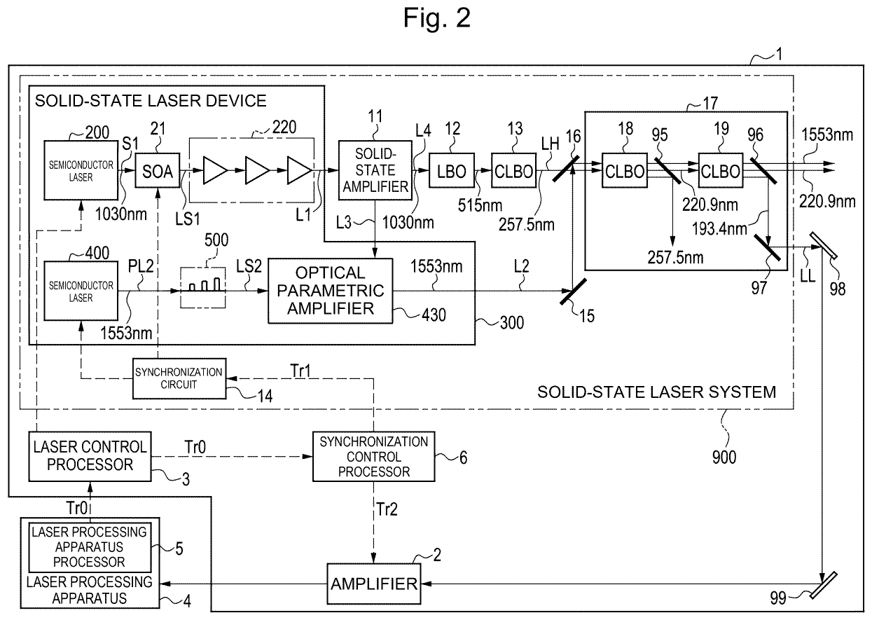

FIG. 2 schematically illustrates a configuration of the excimer laser system 1 according to the first embodiment. The excimer laser system 1 according to the present embodiment differs from the comparative example only in the configuration of the solid-state laser system 900.

In the present embodiment, the synchronization circuit 14 is connected to the semiconductor laser 400 instead of the SOA 41 via a signal line. The synchronization circuit 14 is configured to output a predetermined trigger signal to the semiconductor laser 400 and the SOA 21, respectively, based on the trigger signal Tr1 from the synchronization control processor 6.

In addition, the semiconductor laser 400 and the SOA 21 are synchronously controlled based on the trigger signals supplied from the synchronization circuit 14. The semiconductor laser 400 outputs a single-pulse second pulse laser beam PL2 having a wavelength of about 1553 nm by pulse oscillation.

Further, a burst pulse light generating apparatus 500 is provided instead of the SOA 41, between the semiconductor laser 400 and the optical parametric amplifier 430. The burst pulse light generating apparatus 500 generates the burst pulse light beam LS2 by burst-pulsing the second pulse laser beam PL2.

The other configurations of the solid-state laser system 900 according to the present embodiment are the same as those of the comparative example.

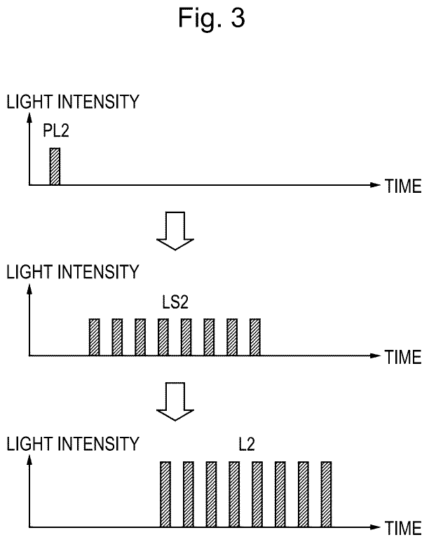

FIG. 3 illustrates the second pulse laser beam PL2 and the burst pulse light beam LS2 according to the first embodiment. As illustrated in FIG. 3, the second pulse laser beam PL2 is converted into the burst pulse light beam LS2 by the burst pulse light generating apparatus 500. The burst pulse light beam LS2 is amplified by the optical parametric amplifier 430 to become the burst pulse light beam L2.

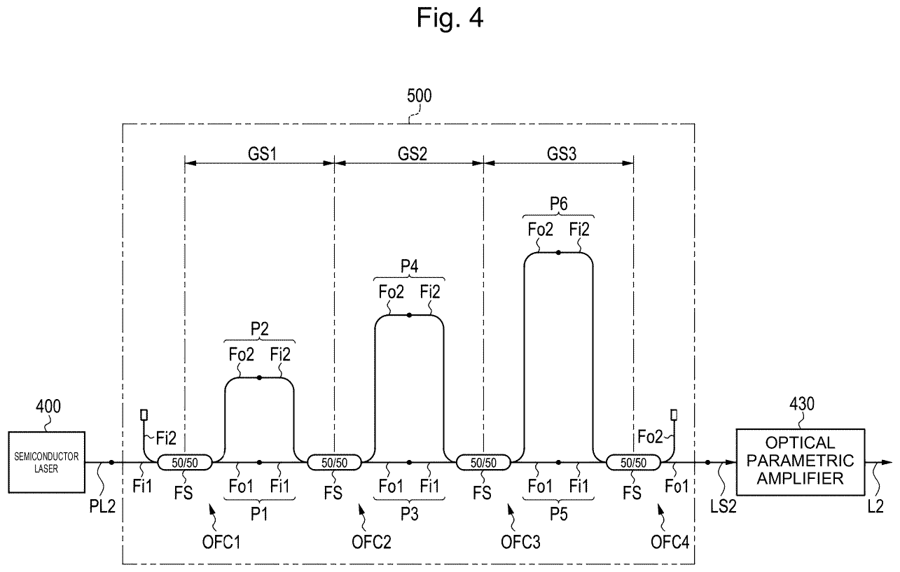

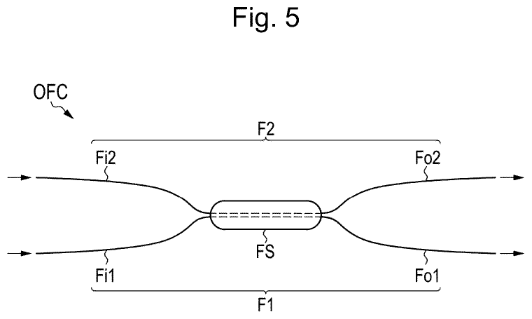

FIG. 4 illustrates a configuration example of the burst pulse light generating apparatus 500. FIG. 5 illustrates a configuration example of an optical fiber coupler OFC. As illustrated in FIG. 4, the burst pulse light generating apparatus 500 is configured by connecting a plurality of optical fiber couplers OFC and has one or more generation stages GS. In each generation stage GS, each pulse laser beam is divided into a plurality of temporally separated pulse laser beams. In the present embodiment, the burst pulse light generating apparatus 500 is configured by connecting four optical fiber couplers OFC1 to OFC4 and has three generation stages GS1 to GS3.

The optical fiber coupler OFC is a fused type fiber coupler made through a process of heating and melting a plurality of optical fibers at specific positions, and then stretching them in a longitudinal direction. In the present embodiment, as illustrated in FIG. 5, the optical fiber coupler OFC is formed by heating and melting two optical fibers F1 and F2 at a predetermined location, and then stretching them in the longitudinal direction. Here, the predetermined location is a part where the optical fibers F1 and F2 are physically and optically coupled, and is referred to as a “coupling part FS” hereinafter.

Therefore, the optical fiber coupler OFC is a fused type fiber coupler of a 2×2 configuration, where two optical fibers Fi1 and Fi2 are connected to an input side of the coupling part FS and two optical fibers Fo1 and Fo2 are connected to an output side.

When light beams are incident on both optical fibers Fi1 and Fi2, the light beams are coupled by interfering with each other at the coupling part FS, and the light beam formed by the coupling is branched into the optical fibers Fo1 and Fo2 according to a predetermined branching ratio by the coupling part FS. In the present embodiment, the branching ratio is set to 50:50. In this case, the light beam formed by the coupling in the coupling part FS is branched into the optical fibers Fo1 and Fo2 in a 50:50 ratio. In FIG. 4, the branching ratio of 50:50 is indicated as “50/50.”

The optical fiber coupler OFC can be used by terminating one of the optical fibers Fi1 and Fi2 on the input side. For example, if the optical fiber Fi2 is terminated and the light beam is incident only on the optical fiber Fi1, the light beam incident on the coupling part FS from the optical fiber Fi1 is branched into the optical fibers Fo1 and Fo2 according to the predetermined branching ratio. When the branching ratio is 50:50, the light beam incident on the optical fiber Fi1 is branched into the optical fibers Fo1 and Fo2 in the 50:50 ratio.

In addition, the optical fiber coupler OFC can be used by terminating one of the optical fibers Fo1 and Fo2 on the output side. For example, when terminating the optical fiber Fo2, it is preferable to provide a light absorbing material or a termination device at an output end of the optical fiber Fo2 so as not to affect the optical fiber Fo1. When the branching ratio is 50:50, 50% of the light beam formed by the coupling in the coupling part FS is branched to the optical fiber Fo1.

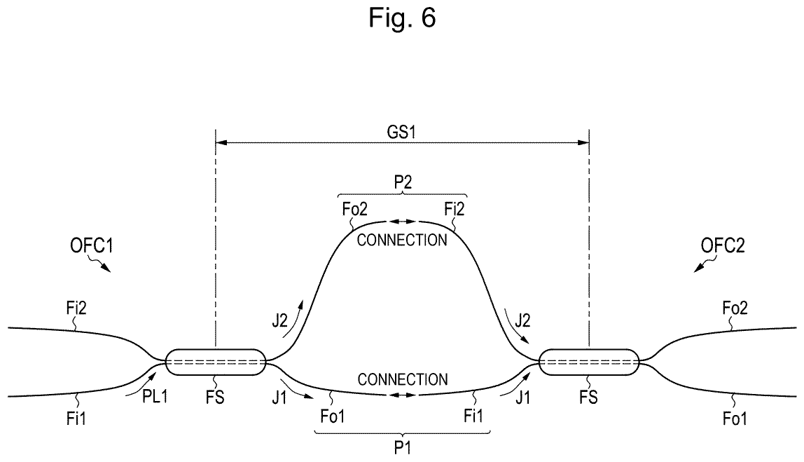

FIG. 6 illustrates a configuration example of the generation stage GS1. The generation stage GS1 is configured by connecting the two optical fiber couplers OFC1 and OFC2.

Specifically, the generation stage GS1 is configured by connecting the optical fibers Fo1 and Fo2 disposed on the output side of the optical fiber coupler OFC1 and the optical fibers Fi1 and Fi2 disposed on the input side of the optical fiber coupler OFC2, respectively. The generation stage GS1 has a first optical path P1 formed by connecting the optical fibers Fo1 and Fi1 and a second optical path P2 formed by connecting the optical fibers Fo2 and Fi2. Lengths of the optical fibers Fo1, Fo2, Fi1, and Fi2 are adjusted such that an optical path length (second optical path length) of the second optical path P2 is longer than an optical path length (first optical path length) of the first optical path P1.

In the generation stage GS1, the optical fiber Fi1 of the optical fiber coupler OFC1 is connected to the semiconductor laser 400, and the optical fiber Fi2 of the optical fiber coupler OFC1 is terminated. The generation stage GS1 receives the second pulse laser beam PL2 from the semiconductor laser 400 via the optical fiber Fi1.

The generation stage GS1 generates a first burst pulse light beam BL1 including two pulse laser beams by branching the second pulse laser beam PL2 into a first branch light beam J1 and a second branch light beam J2, and then coupling the first branch light beam J1 propagated through the first optical path P1 and the second branch light beam J2 propagated through the second optical path P2. In the generation stage GS1, the second optical path P2 is a delay optical path for delaying the second branch light beam J2 relative to the first branch light beam J1.

The generation stage GS2 is configured by connecting the two optical fiber couplers OFC2 and OFC3 similarly to the generation stage GS1. The generation stage GS2 has a third optical path P3 formed by connecting the optical fibers Fo1 and Fi1 and a fourth optical path P4 formed by connecting the optical fibers Fo2 and Fi2. The lengths of the optical fibers Fo1, Fo2, Fi1, and Fi2 are adjusted such that an optical path length (fourth optical path length) of the fourth optical path P4 is longer than an optical path length (third optical path length) of the third optical path P3.

The generation stage GS2 generates a second burst pulse light beam BL2 including four pulse laser beams by branching each pulse laser beam of the first burst pulse light beam BL1 output from the generation stage GS1 into a third branch light beam J3 and a fourth branch light beam J4, and then coupling the third branch light beam J3 propagated through the third optical path P3 and the fourth branch light beam J4 propagated through the fourth optical path P4. In the generation stage GS2, the fourth optical path P4 is a delay optical path for delaying the fourth branch light beam J4 relative to the third branch light beam J3.

The generation stage GS3 is configured by connecting the two optical fiber couplers OFC3 and OFC4 similarly to the generation stage GS2. The generation stage GS3 has a fifth optical path P5 formed by connecting the optical fibers Fo1 and Fi1 and a sixth optical path P6 formed by connecting the optical fibers Fo2 and Fi2. The lengths of the optical fibers Fo1, Fo2, Fi1, and Fi2 are adjusted such that an optical path length (sixth optical path length) of the sixth optical path P6 is longer than an optical path length (fifth optical path length) of the fifth optical path P5.

The generation stage GS3 generates a third burst pulse light beam BL3 including eight pulse laser beams by branching each pulse laser beam of the second burst pulse light beam BL2 output from the generation stage GS2 into a fifth branch light beam J5 and a sixth branch light beam J6, and then coupling the fifth branch light beam J5 propagated through the fifth optical path P5 and the sixth branch light beam J6 propagated through the sixth optical path P6. In the generation stage GS3, the sixth optical path P6 is a delay optical path for delaying the sixth branch light beam J6 relative to the fifth branch light beam J5.

In the generation stage GS3, the optical fiber Fo1 of the optical fiber coupler OFC4 is connected to the Yb fiber amplifier system 220, and the optical fiber Fo2 is terminated. A part of the third burst pulse light beam BL3 is discarded from the optical fiber Fo2, and a remaining component enters the optical parametric amplifier 430 as the burst pulse light beam LS2.

In order to equalize intervals of the pulse laser beams included in the burst pulse light beam LS2, a difference between the third optical path length and the fourth optical path length should be twice a difference between the first optical path length and the second optical path length, and a difference between the fifth optical path length and the sixth optical path length should be twice the difference between the third optical path length and the fourth optical path length. That is, if the difference between the first optical path length and the second optical path length is ΔL, the difference between the third optical path length and the fourth optical path length needs to be 2ΔL, and the difference between the fifth optical path length and the sixth optical path length needs to be 4ΔL. In addition, the first optical path length, the third optical path length, and the fifth optical path length need to be all equal.

In order to temporally separate the pulse laser beams included in the burst pulse light beam LS2, if a pulse width of the second pulse laser beam PL2 is PW and a delay time of the second branch light beam J2 relative to the first branch light beam J1 is Δt, it is necessary to satisfy a relationship in Expression (1) below. Here, the pulse width PW is not a full width at half maximum but is the pulse width that includes rise and fall tails of the pulse.

PW<Δt (1)

Further, if a refractive index of a mode of the second pulse laser beam PL2 propagated through the optical fiber is n and a light speed in vacuum is c, a relationship of Expression (2) below is established.

Δt=ΔL×n/c (2)

From Expression (2), Expression (1) is modified into Expression (3) below.

PW<ΔL×n/c (3)

For example, ΔL is 1.022 m and Δt is 5 ns. In this case, by making the pulse width PW less than 5 ns, it is possible to completely divide the pulse laser beams included in the burst pulse light beam LS2.

In the present embodiment, in order to improve stability and efficiency of wavelength conversion in the wavelength conversion system 17, it is preferable that propagation of each pulse laser beam in the burst pulse light generating apparatus 500 is in a single polarization direction. To achieve this, it is preferable that each of the optical fibers forming the optical fiber coupler OFC is a polarization-maintaining fiber. In this case, it is preferable that the second pulse laser beam PL2 output from the semiconductor laser 400 is linearly polarized and its polarization direction is aligned with a fast axis or a slow axis of the polarization-maintaining fiber. This makes it possible to suppress polarization crosstalk and to maintain high polarization characteristics.

In addition, by fusing the two optical fibers at the coupling part FS as described above, it becomes possible to prevent degradation of polarization characteristics while minimizing loss at the coupling part FS. Note that the two optical fibers may be connected at the coupling part FS using connectors.

Further, when connecting the optical fibers between the two optical fiber couplers OFC, it is preferable to connect them by aligning the fast axes or the slow axes with each other. However, in some cases, they may be connected by aligning the fast axis and the slow axis with each other.

By satisfying these conditions, quality of the burst pulse light beam LL after wavelength conversion is improved while maintaining the polarization characteristics of the pulse light beam L1 and burst pulse light beam L2 in the wavelength conversion system 17.

### 2.2 Operation

The operation of the excimer laser system 1 according to the first embodiment is same as that of the comparative example, except that the synchronization circuit 14 outputs a trigger signal to the semiconductor laser 400 and that the burst pulse light generating apparatus 500 generates the burst pulse light beam LS2 instead of the SOA 41. Hereinafter, a generation operation of the burst pulse light beam LS2 will be described.

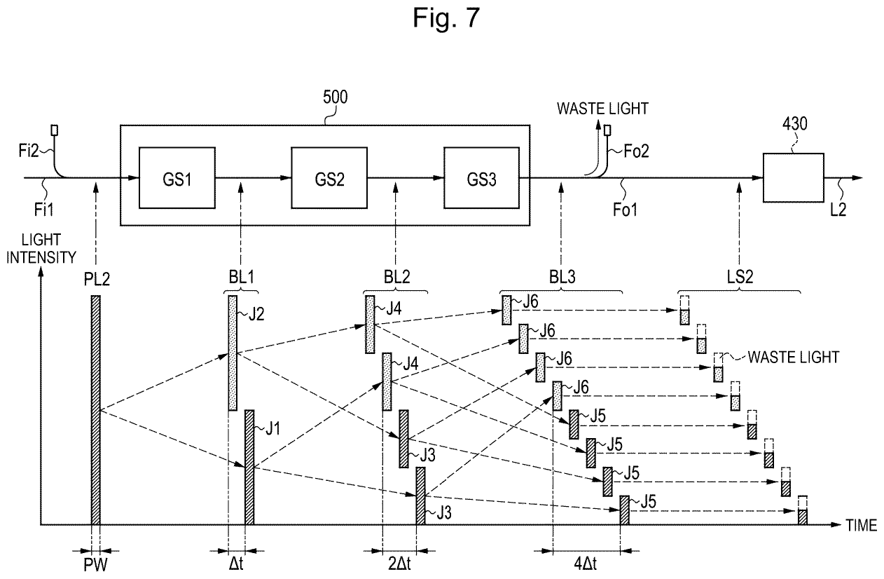

FIG. 7 illustrates a flow of generating the burst pulse light beam LS2 from the second pulse laser beam PL2. When a trigger signal is input from the synchronization circuit 14, the semiconductor laser 400 performs the pulse oscillation and outputs a one-pulse second pulse laser beam PL2. The second pulse laser beam PL2 enters the burst pulse light generating apparatus 500 and then enters the generation stage GS1 first. In the generation stage GS1, the second pulse laser beam PL2 is branched into the first branch light beam J1 and the second branch light beam J2, the second branch light beam J2 is delayed by the delay time Δt relative to the first branch light beam J1, and then both are coupled to be converted to a two-pulse first burst pulse light beam BL1.

Next, the first burst pulse light beam BL1 enters the generation stage GS2. In the generation stage GS2, each pulse laser beam of the first burst pulse light beam BL1 is branched into the third branch light beam J3 and the fourth branch light beam J4, the fourth branch light beam J4 is delayed by a delay time 2Δt relative to the third branch light beam J3, and then both are coupled to be converted to a four-pulse second burst pulse light beam BL2.

Then, the second burst pulse light beam BL2 enters the generation stage GS3. In the generation stage GS3, each pulse laser beam of the second burst pulse light beam BL2 is branched into the fifth branch light beam J5 and the sixth branch light beam J6, the sixth branch light beam J6 is delayed by a delay time 4Δt relative to the fifth branch light beam J5, and then both are coupled to be converted to an eight-pulse third burst pulse light beam BL3.

Thereafter, the third burst pulse light beam BL3 is partially discarded as waste light based on the branching ratio, and the remaining component enters the optical parametric amplifier 430 as the burst pulse light beam LS2.

Since the branching ratios at the coupling parts FS in the generation stages GS1 to GS3 are all 50:50 as being equally balanced, the pulse laser beams included in the third burst pulse light beam BL3 have uniform light intensity.

### 2.3 Effect

According to the present embodiment, the burst pulse light generating apparatus is configured to generate a two-pulse burst pulse light beam by branching a one-pulse pulse laser beam into two branch light beams, delaying one with a delay optical path, and coupling them. Therefore, in the present embodiment, the burst pulse light generating apparatus can be configured using an optical fiber coupler without using an SOA or an LNM. Thus, it is possible to provide a solid-state laser system that is inexpensive and has a low risk of failure, and an excimer laser system provided with the solid-state laser system.

In addition, in the present embodiment, since the burst pulse light generating apparatus is configured by connecting the generation stages in series, it is possible to generate a burst pulse light beam including a large number of pulse laser beams.

Further, in the present embodiment, since each generation stage is formed of the optical fiber coupler of the 2×2 configuration and each branching ratio is equally balanced, optical conversion efficiency is high. Specifically, since ½ of the components of the burst pulse light beam are discarded as waste light in the final generation stage, the optical conversion efficiency is 50%. For example, it is conceivable to use the optical fiber coupler of the 2×2 configuration to generate the eight-pulse burst pulse light beam in one generation stage, however, in that case, since ⅞ of the components of the burst pulse light beam are discarded as waste light in the final generation stage, the conversion efficiency drops to 12.5%. Therefore, when prioritizing the optical conversion efficiency, a configuration that generates the burst pulse light beam by repeating branching into two is suitable, as in the present embodiment.

### 3. Second Embodiment

Next, the second embodiment of the present disclosure will be described. A configuration of the excimer laser system according to the present embodiment differs from that of the first embodiment only in the configuration of the burst pulse light generating apparatus 500 and use of an Er-doped fiber amplifier system 420 instead of the optical parametric amplifier 430.

### 3.1 Configuration

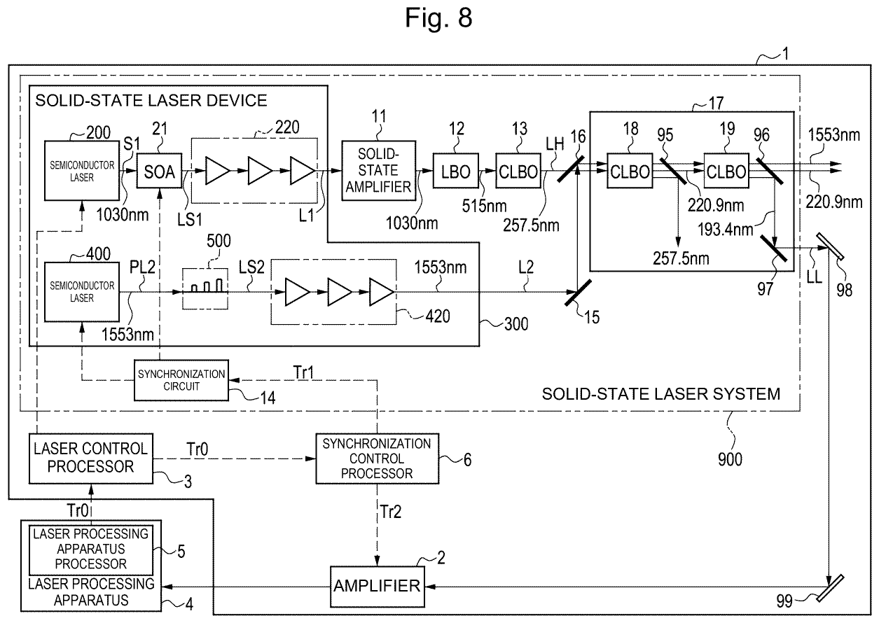

FIG. 8 schematically illustrates the configuration of the excimer laser system 1 according to the second embodiment. The excimer laser system 1 according to the present embodiment differs from that of the first embodiment only in the configuration of the solid-state laser device 300.

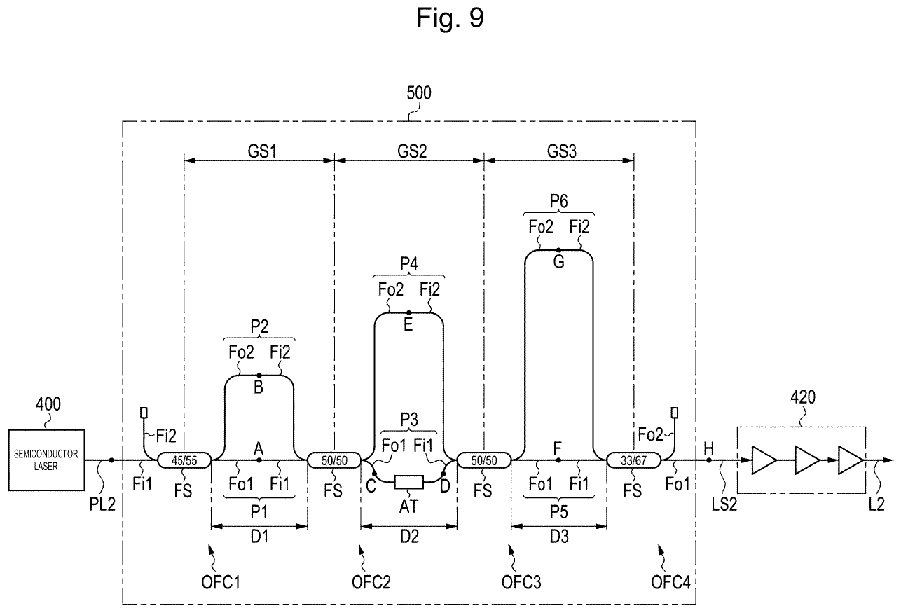

FIG. 9 illustrates a configuration example of the burst pulse light generating apparatus 500 according to the second embodiment. The present embodiment aims to generate the burst pulse light beam LS2 including the pulse laser beams with gradually increasing light intensity, and differs from the first embodiment in following points.

In the present embodiment, the branching ratios of the optical fiber couplers OFC1 to OFC4 are set to 45:55, 50:50, 50:50, and 33:67, respectively. The optical fiber couplers OFC1 to OFC4 may be configured such that at least one of the branching ratios between the first branch light beam J1 and the second branch light beam J2, the third branch light beam J3 and the fourth branch light beam J4, and the fifth branch light beam J5 and the sixth branch light beam J6 is unbalanced.

In the present embodiment, an attenuator AT is disposed in the third optical path P3. The attenuator AT reduces the light intensity of the third branch light beam J3 propagated through the third optical path P3. For example, the attenuator AT is an inline type attenuator provided with optical fibers on input and output sides of an element that has a function of attenuating the propagated light. Examples of the element used in the attenuator AT include an element formed by sandwiching an optical fiber doped with metal ions that absorb light in a core or a filter that absorbs or reflects light between the optical fiber on the input side and the optical fiber on the output side. In the present embodiment, the attenuator AT is a 3 dB attenuator.

### 3.2 Operation

The operation of the excimer laser system 1 according to the second embodiment differs from that of the first embodiment only in generation processing of the burst pulse light beam LS2 by the burst pulse light generating apparatus 500 and generation processing of the burst pulse light beam L2 which is its amplified light.

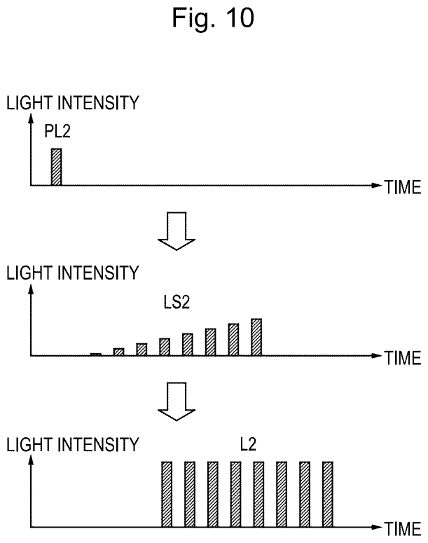

FIG. 10 illustrates the second pulse laser beam PL2 and the burst pulse light beam LS2 according to the second embodiment. In the present embodiment, as illustrated in FIG. 10, the second pulse laser beam PL2 is converted into the burst pulse light beam LS2 with gradually increasing pulse intensity by the burst pulse light generating apparatus 500. This burst pulse light beam LS2 is amplified by the Er-doped fiber amplifier system 420 to become the burst pulse light beam L2.

First, following optical path lengths are defined with reference to FIG. 9. The optical path length of the first optical path P1 passing through a point A is defined as D1, the optical path length of the third optical path P3 passing through points C and D is defined as D2, and the optical path length of the fifth optical path P5 passing through a point F is defined as D3. Here, the optical path length D2 includes the optical path length within the attenuator AT.

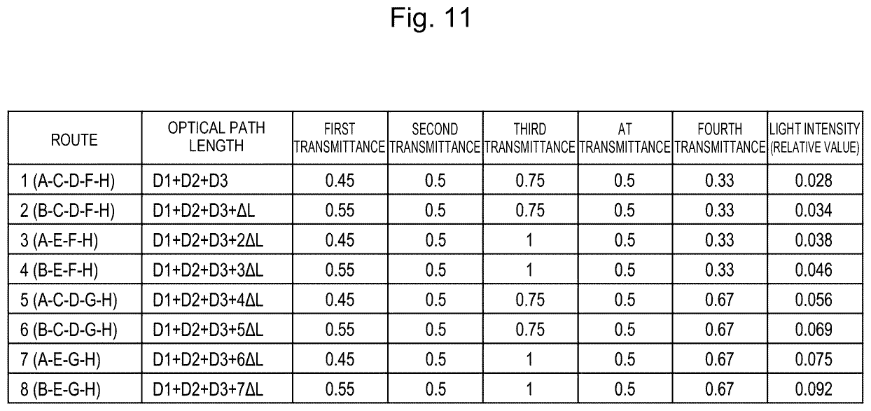

FIG. 11 illustrates calculated values of light intensity of pulse laser beams included in the burst pulse light beam LS2 generated by the burst pulse light generating apparatus 500 according to the second embodiment. Routes 1 to 8 are all routes from an input end of the optical fiber coupler OFC1 to a point H that is an output end of the optical fiber coupler OFC4. FIG. 11 illustrates optical path lengths, first to fourth transmittances, and AT transmittances of the routes 1 to 8. The first to fourth transmittances are transmittances of the optical fiber couplers OFC1 to OFC4 in each route, and correspond to the branching ratios. The AT transmittance is a transmittance of the attenuator AT. For each route, a value calculated as an infinite product of the first to fourth transmittances and the AT transmittance corresponds to the light intensity of each pulse laser beam included in the burst pulse light beam LS2.

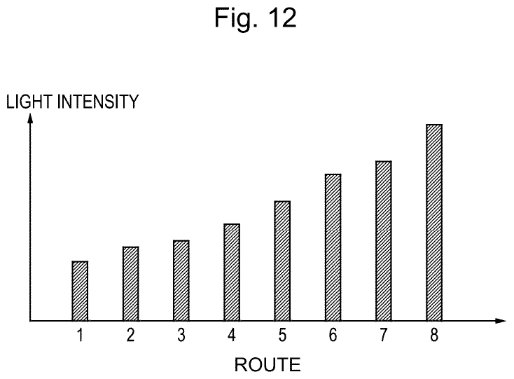

FIG. 12 illustrates a difference in light intensity for each route illustrated in FIG. 11. This graph shows that each pulse laser beam included in the burst pulse light beam LS2 generated by the burst pulse light generating apparatus 500 according to the present embodiment gradually increases in light intensity over time.

### 3.3 Effect

In the Er-doped fiber amplifier system 420, the pulse laser beam is amplified using excitation energy in the medium, however, when the light intensity is high, the energy of the medium is all consumed, leading to gain saturation where an amplification factor decreases. When the gain saturation occurs, the amplification factor of the subsequently incident pulse laser beam decreases, which may result in uneven light intensity between the pulses of the amplified burst pulse light beam L2.

In the present embodiment, since the burst pulse light beam LS2 with gradually increasing light intensity enters the Er-doped fiber amplifier system 420, effects of the gain saturation are mitigated. Thus, the uneven light intensity between the pulses is suppressed for the amplified burst pulse light beam L2.

Next, various modifications according to the embodiments will be described.

### 4. First Modification

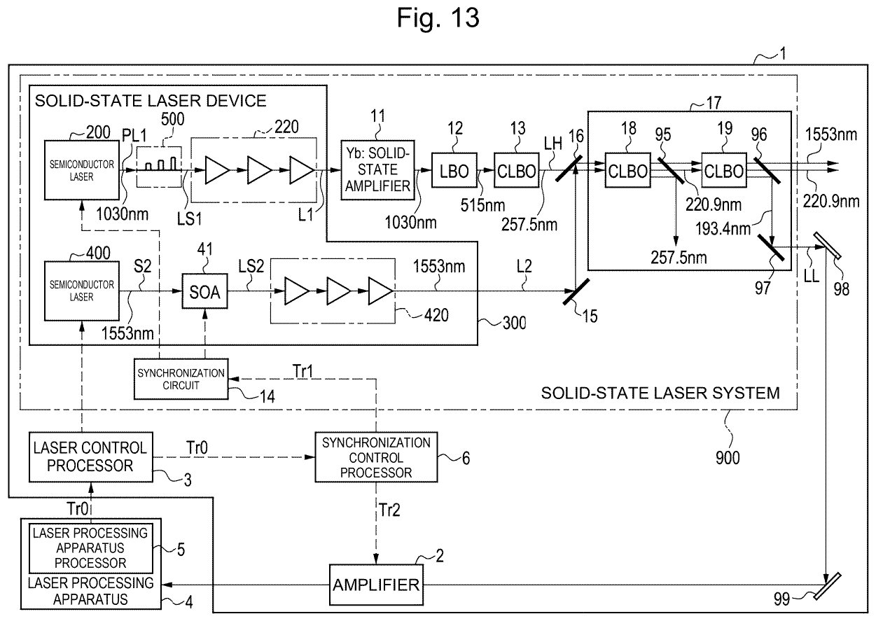

FIG. 13 schematically illustrates a configuration of the excimer laser system 1 according to the first modification. In the present modification, the synchronization circuit 14 is connected to the semiconductor laser 200 and the SOA 41 via signal lines. The synchronization circuit 14 is configured to output predetermined trigger signals to the semiconductor laser 200 and the SOA 41 based on the trigger signal Tr1 from the synchronization control processor 6.

In addition, the semiconductor laser 200 is synchronously controlled based on the trigger signal supplied from the synchronization circuit 14. In the present modification, the semiconductor laser 200 outputs a single-pulse first pulse laser beam PL1 having a wavelength of about 1030 nm by the pulse oscillation. The semiconductor laser 400 outputs the seed light beam S2 having a wavelength of about 1553 nm by the CW oscillation.

Further, instead of the SOA 21, the burst pulse light generating apparatus 500 is provided between the semiconductor laser 200 and the Yb fiber amplifier system 220. The burst pulse light generating apparatus 500 has a configuration same as that of the burst pulse light generating apparatus 500 according to the second embodiment, and generates the burst pulse light beam LS1 by burst-pulsing the first pulse laser beam PL1.

The burst pulse light generating apparatus 500 includes a generation stage that generates a second burst pulse light beam including two pulse laser beams by branching the first pulse laser beam PL1 into first branch light beam and second branch light beam and then coupling the first branch light beam and the second branch light beam.

The SOA 41 connected to the semiconductor laser 400 pulses the seed light beam S2 to generate the pulse light beam LS2, which then enters the Er-doped fiber amplifier system 420. Similar effects as those of the embodiments can be obtained in the configuration of the present modification as well.

### 5. Second Modification

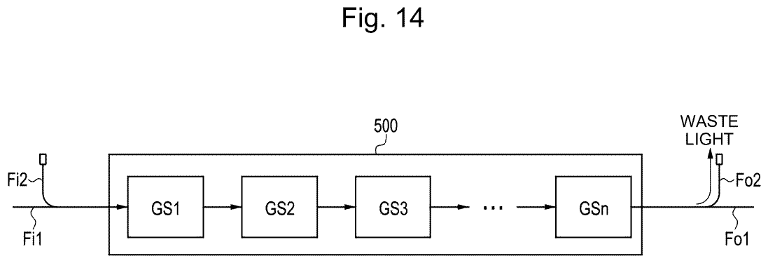

FIG. 14 schematically illustrates a configuration of the burst pulse light generating apparatus 500 according to the second modification. The burst pulse light generating apparatus 500 is configured by connecting n pieces of generation stages GS1 to GSn in series. The number of pulse laser beams included in one burst pulse light beam is 2ⁿ. Here, n is an integer equal to or larger than one. For example, if 16 pulse laser beams are to be included in one burst pulse light beam, n should be set to 4. Note that the larger the value of n, the longer the length of the delay optical path in the generation stage GSn.

### 6. Third Modification

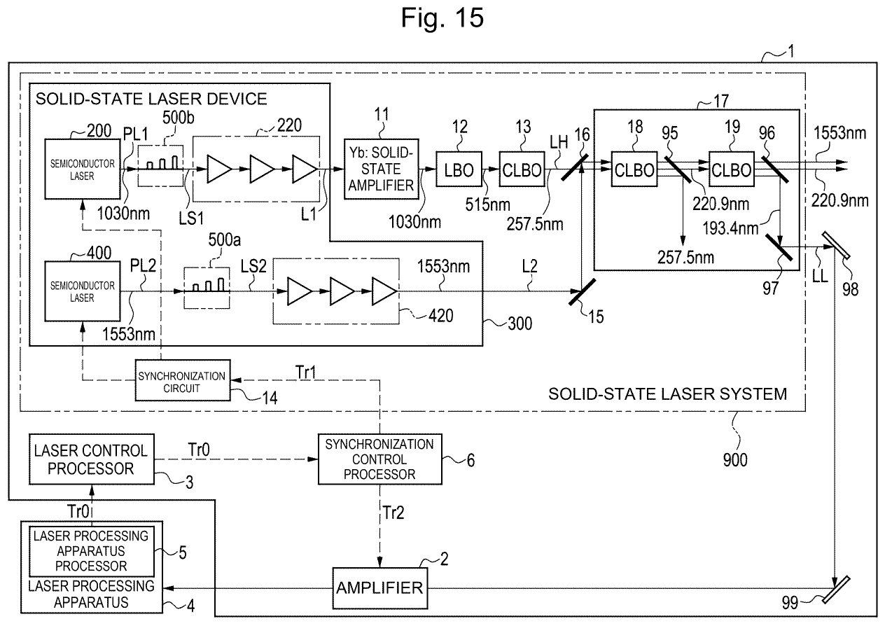

FIG. 15 schematically illustrates a configuration of the excimer laser system 1 according to the third modification. In the present modification, the synchronization circuit 14 is connected to the semiconductor laser 200 and the semiconductor laser 400 via signal lines. The synchronization circuit 14 is configured to output predetermined trigger signals to the semiconductor laser 200 and the semiconductor laser 400 based on the trigger signal Tr1 from the synchronization control processor 6.

In addition, in the present modification, the semiconductor laser 200 and the semiconductor laser 400 are synchronously controlled based on the trigger signals supplied from the synchronization circuit 14. In the present modification, the semiconductor laser 200 outputs the single-pulse first pulse laser beam PL1 having a wavelength of about 1030 nm by the pulse oscillation. The semiconductor laser 400 outputs the single-pulse second pulse laser beam PL2 having a wavelength of about 1553 nm by the pulse oscillation.

In the present modification, instead of the SOA 41, a burst pulse light generating apparatus 500a is provided between the semiconductor laser 400 and the Er-doped fiber amplifier system 420. The burst pulse light generating apparatus 500a has a configuration same as that of the burst pulse light generating apparatus 500 according to the second embodiment, and generates the burst pulse light beam LS2 by burst-pulsing the second pulse laser beam PL2.

Further, in the present modification, instead of the SOA 21, a burst pulse light generating apparatus 500b is provided between the semiconductor laser 200 and the Yb fiber amplifier system 220. The burst pulse light generating apparatus 500b has a configuration same as that of the burst pulse light generating apparatus 500 according to the second embodiment, and generates the burst pulse light beam LS1 by burst-pulsing the first pulse laser beam PL1.

In the burst pulse light generating apparatus 500b, the generation stages are connected in series. For example, the burst pulse light generating apparatus 500b includes three generation stages connected in series, and generates the first to sixth branch light beams to generate the eight-pulse third burst pulse light beam.

The burst pulse light generating apparatus 500b includes at least one generation stage, and includes the generation stage that generates a fourth burst pulse light beam including two pulse laser beams by branching the first pulse laser beam PL1 into a seventh branch light beam and an eighth branch light beam and then coupling the seventh branch light beam and the eighth branch light beam.

Note that the burst pulse light generating apparatus 500b includes three generation stages connected in series, similarly to the burst pulse light generating apparatus 500a, and generates an eight-pulse sixth burst pulse light beam.

Further, while a burst pulse light generator configured including an optical fiber coupler is illustrated in the embodiments, it is also possible to realize it with a PLC (Planar Lightwave Circuit) circuit using a silicon substrate or a glass substrate instead of the optical fiber coupler. In this case, a route requiring an optical path difference can be realized by forming a silicon waveguide or a glass waveguide.

When the PLC circuit is used, the optical path difference, the branching ratio, attenuation, and the like can be precisely controlled by a mask pattern of the waveguide on the substrate. Therefore, it becomes possible to highly accurately control a pulse interval of the burst pulse light beam, the branching ratio, the light intensity of each pulse, and the like. Moreover, since the pulse interval can be set precisely, it becomes possible to shorten the pulse interval further.

Further, in the PLC circuit, each optical element can be disposed at a high density, making miniaturization possible. In particular, a silicon substrate has a higher refractive index compared to a glass substrate, and the required optical path difference can be achieved with a shorter distance. Therefore, the configuration using a silicon substrate can achieve further miniaturization.

In addition, as an optical fiber coupler, a partial mirror type coupler may be used instead of a fused type fiber coupler.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined. The terms used throughout the present specification and the appended claims should be interpreted as “non-limiting” terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A solid-state laser system comprising:
a first semiconductor laser device configured to output a first pulse laser beam having a first wavelength; and
a first burst pulse light generating apparatus including a first generation stage that generates a first burst pulse light beam including two pulse laser beams by branching the first pulse laser beam into a first branch light beam and a second branch light beam, and then coupling the first branch light beam and the second branch light beam,
the first generation stage including
a first optical path having a first optical path length for propagating the first branch light beam, and
a second optical path having a second optical path length, which is longer than the first optical path length, for propagating the second branch light beam.

2. The solid-state laser system according to claim 1, wherein
the first burst pulse light generating apparatus includes a second generation stage that generates a second burst pulse light beam including four pulse laser beams by branching each pulse laser beam included in the first burst pulse light beam into a third branch light beam and a fourth branch light beam, and then coupling the third branch light beam and the fourth branch light beam, and
the second generation stage includes
a third optical path having a third optical path length for propagating the third branch light beam, and
a fourth optical path having a fourth optical path length, which is longer than the third optical path length, for propagating the fourth branch light beam.

3. The solid-state laser system according to claim 2, wherein
the first burst pulse light generating apparatus includes a third generation stage that generates a third burst pulse light beam including eight pulse laser beams by branching each pulse laser beam included in the second burst pulse light beam into a fifth branch light beam and a sixth branch light beam, and then coupling the fifth branch light beam and the sixth branch light beam, and
the third generation stage includes
a fifth optical path having a fifth optical path length for propagating the fifth branch light beam, and
a sixth optical path having a sixth optical path length, which is longer than the fifth optical path length, for propagating the sixth branch light beam.

4. The solid-state laser system according to claim 3, wherein
an optical path difference between the third optical path length and the fourth optical path length is twice an optical path difference between the first optical path length and the second optical path length, and
an optical path difference between the fifth optical path length and the sixth optical path length is twice the optical path difference between the third optical path length and the fourth optical path length.

5. The solid-state laser system according to claim 3, wherein
the first optical path, the second optical path, the third optical path, the fourth optical path, the fifth optical path, and the sixth optical path are each formed of optical fibers.

6. The solid-state laser system according to claim 3, wherein
a branching ratio of the first branch light beam and the second branch light beam, a branching ratio of the third branch light beam and the fourth branch light beam, and a branching ratio of the fifth branch light beam and the sixth branch light beam are all equally balanced.

7. The solid-state laser system according to claim 6, wherein
the pulse laser beams included in the third burst pulse light beam have uniform light intensity.

8. The solid-state laser system according to claim 3, wherein
at least one of a branching ratio of the first branch light beam and the second branch light beam, a branching ratio of the third branch light beam and the fourth branch light beam, and a branching ratio of the fifth branch light beam and the sixth branch light beam is unbalanced.

9. The solid-state laser system according to claim 8, wherein
the pulse laser beams included in the third burst pulse light beam gradually increase in light intensity.

10. The solid-state laser system according to claim 3, wherein
the first optical path length, the third optical path length, and the fifth optical path length are all equal.

11. The solid-state laser system according to claim 3, comprising:
a fiber amplifier disposed in a subsequent stage of the first burst pulse light generating apparatus; and
an attenuator disposed in the third optical path.

12. The solid-state laser system according to claim 1, wherein
when a pulse width of the first pulse laser beam is PW, an optical path difference between the first optical path length and the second optical path length is ΔL, a refractive index of a mode of the first pulse laser beam propagated through optical fibers forming the first optical path length and the second optical path length is n, and a light speed in vacuum is c, a relationship of PW<ΔL×n/c is satisfied.

13. The solid-state laser system according to claim 1, comprising:
a second semiconductor laser device configured to output a second pulse laser beam having a second wavelength; and
a second burst pulse light generating apparatus including a generation stage that generates a fourth burst pulse light beam including two pulse laser beams by branching the second pulse laser beam into a seventh branch light beam and an eighth branch light beam, and then coupling the seventh branch light beam and the eighth branch light beam, wherein
the generation stage includes
a seventh optical path having a seventh optical path length for propagating the seventh branch light beam, and
an eighth optical path having an eighth optical path length, which is longer than the seventh optical path length, for propagating the eighth branch light beam.

14. An excimer laser apparatus comprising:
a solid-state laser system including
a first semiconductor laser device configured to output a first pulse laser beam having a first wavelength, and
a first burst pulse light generating apparatus including a first generation stage that generates a first burst pulse light beam including two pulse laser beams by branching the first pulse laser beam into a first branch light beam and a second branch light beam, and then coupling the first branch light beam and the second branch light beam,
the first generation stage including
a first optical path having a first optical path length for propagating the first branch light beam, and
a second optical path having a second optical path length, which is longer than the first optical path length, for propagating the second branch light beam;
a wavelength conversion system configured to generate and output a seed light beam based on the first burst pulse light beam; and
an amplifier configured to amplify the seed light.

15. A solid-state laser system comprising:
a semiconductor laser device configured to output a pulse laser beam; and
a burst pulse light generating apparatus including one or more generation stages that generate a burst pulse light beam by branching the pulse laser beam into two and then coupling the branch light beams,
the burst pulse light generating apparatus including, when n is an integer equal to or larger than one, n pieces of the generation stages connected in series, and generating the burst pulse light beam including 2ⁿ pieces of pulse laser beams.
